(19) United States
(12) Patent Application Publication
(10) Pub. No.: US 2025/0201738 A1
(43) Pub. Date: Jun. 19, 2025

(54) DIE WITH BOND PAD

(71) Applicant: TEXAS INSTRUMENTS INCORPORATED, DALLAS, TX (US)

(72) Inventors: JEFFREY SOLAS, ILOILO CITY (PH); JOMARI AUSTRIA, MALABON CITY (PH); RAY FREDRIC DE ASIS, MABALACAT (PH); JOSE ARVIN PLOMANTES, DAGUPAN (PH)

(21) Appl. No.: 18/538,557

(22) Filed: Dec. 13, 2023

(51) Int. Cl. H01L 23/00

(52) U.S. Cl. CPC H01L 24/03; H01L 24/05; H01L 24/48; H01L 24/94; H01L 2224/03462; H01L 2224/05147; H01L 2224/48105; H01L 2224/48225; H01L 2224/48647; H01L 2224/94; H01L 2924/2064

(57) ABSTRACT

A method for forming an IC (integrated circuit) package includes electroplating a wafer to form a nanotwin copper bond pad on the wafer. The electroplating includes applying a pulsed current to the wafer immersed in a plating solution. The nanotwin copper bond pad is formed with a copper grain that includes a crystal lattice structure that has Miller indices of 111. The method includes singulating a die from the wafer. The die includes the nanotwin copper bond pad. The method also includes mounting the die on an interconnect and attaching a bond wire to the nanotwin copper bond pad to form a copper-to-copper bond between the bond wire and the nanotwin copper bond pad.

### TECHNICAL FIELD

This description relates to a die with an IC (integrated circuit) package that includes a die with a bond pad.

### BACKGROUND

A bond pad is a small area or pad on the surface of an IC (integrated circuit) package that is designed for the attachment of external electrical connections, sometimes in the form of bond wires. These external connections are used to link the IC package to other components, such as other IC packages, PCBs (printed circuit boards) or other parts of an electronic system.

Bond pads facilitate the proper functioning of integrated circuits because bond pads provide a path for electrical signals to enter and exit the IC package. Bond pads are typically formed of metal and are located on the topmost layer of a die of the IC package. Bond pads are designed and positioned on the IC package to ensure reliable and low-resistance connections.

The process of connecting external wires or bumps to bond pads is performed using specialized equipment, such as wire bonding machines or solder reflow processes. The choice of bonding method (wire bonding, flip-chip bonding, etc.) depends on the specific requirements of the IC package and the overall electronic system design. Properly bonded connections are critical for the performance, reliability and functionality of semiconductor devices in a wide range of applications, from consumer electronics to industrial equipment and more.

### SUMMARY

A first example relates to a method for forming an IC (integrated circuit) package. The method includes electroplating a wafer to form a nanotwin copper bond pad on the wafer. The electroplating includes applying a pulsed current to the wafer immersed in a plating solution. The nanotwin copper bond pad is formed with a copper grain that includes a crystal lattice structure that has Miller indices of 111. The method includes singulating a die from the wafer. The die includes the nanotwin copper bond pad. The method also includes mounting the die on an interconnect and attaching a bond wire to the nanotwin copper bond pad to form a copper-to-copper bond between the bond wire and the nanotwin copper bond pad.

A second example relates to a method for forming an IC package. The method includes singulating a die from a wafer, with the die including a nanotwin copper bond pad coupled to a circuit embedded in the die. The nanotwin copper bond pad is formed with a copper grain that includes a crystal lattice structure that has Miller indices of 111. The method also includes mounting the die on an interconnect and attaching a bond wire to the nanotwin copper bond pad to form a copper-to-copper bond between the bond wire and the nanotwin copper bond pad and to couple the circuit embedded in the die to a lead of the interconnect.

A third example relates to an IC (integrated circuit) package including a die having a nanotwin copper bond pad coupled to a circuit embedded in the die. The nanotwin copper bond pad is formed with a copper grain that includes a crystal lattice structure that has Miller indices of 111. The IC package also includes a bond wire coupled to the nanotwin copper bond pad and to a lead of an interconnect. The bond wire and the nanotwin copper bond pad form a copper-to-copper bond.

### BRIEF DESCRIPTION OF THE DRAWINGS

FIG. 1 illustrates a cross-section view of an IC (integrated circuit) package that includes a first copper bond pad and a second copper bond pad.

FIG. 2 illustrates an expanded view of a region that includes a copper-to-copper (Cu—Cu) bond between a copper bond pad and a bond wire of FIG. 1.

FIG. 3 illustrates graphs depicting plating operations for electroplating.

FIG. 4 illustrates a cross-section of crystal lattices formed with the plating operations characterized by the graphs of FIG. 3.

FIG. 5 illustrates an image of a bond wire attached to a nanotwin copper (ntCu) bond pad having a copper grain with a crystal lattice structure having Miller indices of (111).

FIG. 6 illustrates another image of a bond wire attached to a nanotwin copper (ntCu) bond pad having a copper grain with a crystal lattice structure having Miller indices of (111).

FIG. 7 illustrates an image of a pair of bond wires that have been sheared from a first nanotwin copper (ntCu) pad.

FIG. 8 illustrates another image of a pair of bond wires that have been sheared from a second nanotwin copper (ntCu) pad.

FIG. 9 illustrates a graph that plots a shear area of samples of nanotwin copper pads.

FIG. 10 illustrates a bar chart that plots a shear strength for samples of nanotwin copper pads.

FIGS. 11-15 illustrate operations of a method for forming an IC package with a copper bond pad.

FIG. 16 illustrates a flowchart of an example method for fabricating an IC package with a copper bond pad.

### DETAILED DESCRIPTION

This description relates to an IC (integrated circuit) package and a method for forming the IC package. The IC package includes a die having a nanotwin copper bond pad coupled to a circuit embedded in a die of the IC package. The nanotwin copper bond pad is formed with a copper grain that includes a crystal lattice structure that has Miller indices of (111), alternatively notated as 111. A bond wire is coupled to the nanotwin copper bond pad and to a lead of an interconnect (e.g., a lead frame). The wire bond and the nanotwin copper bond pad form a copper-to-copper (Cu—Cu) bond. The copper-to-copper (Cu—Cu) bond has a bond area of about 70% to about 95% of an interface between the bond wire and the nanotwin copper (ntCu) bond pad. Thus, by forming the nanotwin copper (ntCu) bond pad in this manner, the need for expensive materials for the bond pad, such as nickel (Ni) and/or palladium (Pd) is obviated.

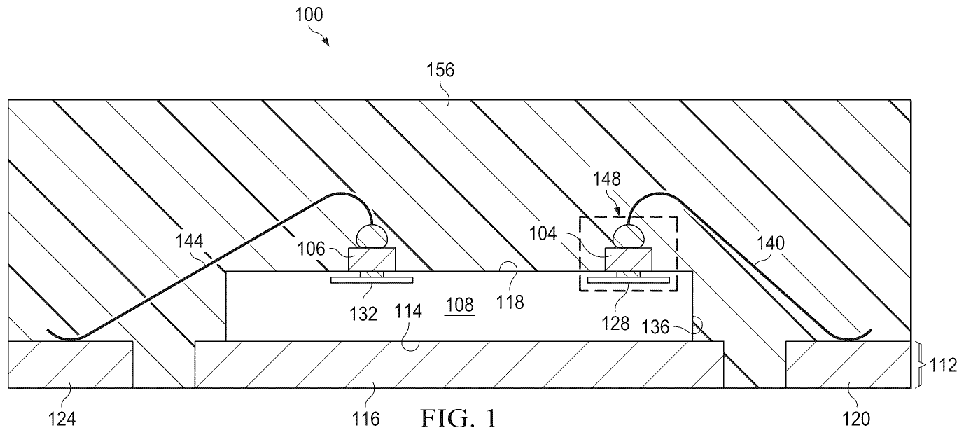

FIG. 1 illustrates a cross-section view of an IC (integrated circuit) package 100 that includes a first copper bond pad 104 and a second copper bond pad 106. The IC package 100 includes a die 108 mounted on an interconnect 112. More specifically, a first side 114 of the die 108 is mounted on a die attach pad 116 of the interconnect 112. A second side 118 of the die 108 opposes the first side 114 of the die 108. Moreover, the first copper bond pad 104 and a second copper bond pad 106 are situated on the second side 118 of the die 108. In some examples, the interconnect 112 is alternatively referred to as a lead frame. The interconnect 112 includes a first lead 120 and a second lead 124. In other examples, there are more or less leads on the interconnect 112.

The first copper bond pad 104 is coupled to a first circuit 128 (e.g., a circuit module) embedded in the die 108 and the second copper bond pad 106 is coupled to a second circuit 132 (e.g., a circuit module) embedded in the die 108. In the example illustrated, the first copper bond pad 104 is proximate to an edge 136 of the die 108. For simplification, it is presumed that the edge 136 of the die 108 forms a periphery of the die 108. Conversely, in the illustrated example, the second copper bond pad 106 is proximate to a center region of the die 108 and distal to the edge 136. However, in other examples, the second copper bond pad 106 is proximate to the edge 136 of the die 108. In some examples, the first copper bond pad 104 and/or the second copper bond pad 106 are implemented as BOAC (bond over active circuit connection) connections to the respective first circuit 128 and/or second circuit 132.

The first lead 120 is connected to the first copper bond pad 104 with a first bond wire 140. The second lead 124 is connected to the second copper bond pad 106 with a second bond wire 144. The first bond wire 140 and the second bond wire 144 are formed with copper wires that have a diameter between about 17.78 micrometers (μm) and about 50.8 μm. The first copper bond pad 104 and the second copper bond pad 106 are formed with copper (Cu). Thus, the first bond wire 140 and the first copper bond pad 104 form a copper-to-copper (Cu—Cu) bond. In a similar manner, the second bond wire 144 and the second copper bond pad 106 form a copper-to-copper (Cu—Cu) bond.

To ensure a high rate of diffusion and to strengthen the copper-to-copper (Cu—Cu) bond, the first copper bond pad 104 and the second copper bond pad 106 are formed with nanotwin copper (ntCu). The nanotwin copper (ntCu) forming the first copper bond pad 104 and the second copper bond pad 106 have a copper grain that includes a crystal lattice with Miller indices of (111), alternatively notated as 111.

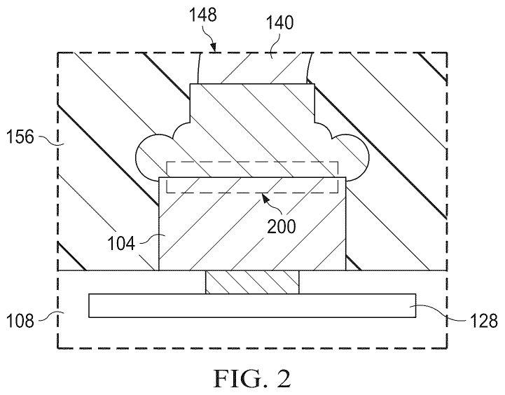

FIG. 2 illustrates an expanded view of a region 148 that includes the copper-to-copper (Cu—Cu) bond between the first copper bond pad 104 and the first bond wire 140. Thus, FIGS. 1 and 2 employ the same reference numbers to denote the same features.

In FIG. 2, a copper-to-copper (Cu—Cu) bond 200 is formed between the first copper bond pad 104 and the first bond wire 140. The nanotwin copper (ntCu) including the crystal lattice with the Miller indices of (111) enables a high rate of diffusion of atoms across the copper-to-copper (Cu—Cu) bond 200. Stated differently, the nanotwin copper (ntCu) forming the first copper bond pad 104 has a high rate of diffusion of atoms to strengthen the copper-to-copper (Cu—Cu) bond 200. As noted, the first bond wire 140 has a diameter between about 17.78 μm and about 50.8 μm. The first copper bond pad 104 has a thickness of about 6 μm to about 15 μm and a width of about 15 μm to about 55 μm. In such a situation, the copper-to-copper (Cu—Cu) bond 200 has a bond area of about 70% to about 95% of an interface between the first bond wire 140 and the first copper bond pad 104. As some specific examples, the bond area is about 76% of the interface or about 89% of the interface.

Referring back to FIG. 1, the IC package 100 is encapsulated with a mold compound 156. In some examples, the mold compound is a plastic. By implementing the first copper bond pad 104 and the second copper bond pad 106 with nanotwin copper (ntCu) having the crystal lattice with the Miller indices of (111) provides a larger bond area than a conventional bond pad formed with polycrystal copper. This increase in the bond area allows the nanotwin copper (ntCu) to obviate the need for expensive materials such as palladium (Pd) and nickel (Ni).

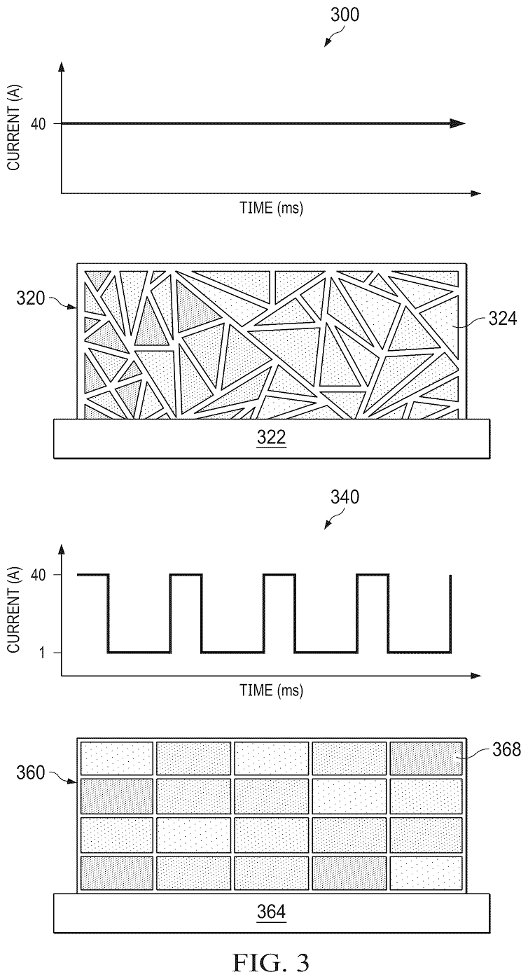

FIGS. 3-6 illustrates operations for fabricating a copper-to-copper (Cu—Cu) bond, such as the copper-to-copper (Cu—Cu) bond 200 of FIG. 2.

More particularly, FIG. 3 illustrates a first graph 300 depicting a conventional direct plating operation for electroplating. The first graph 300 plots an applied current, in amperes (A) as a function of time, in millisecond (ms) employed to form a polycrystal structure 320. In the example illustrated, it is presumed that a wafer 322 is immersed in a solution with a copper concentration of about 32 grams per liter (g/L) or about 55 g/L. In some examples, this solution is referred to as a plating solution. Moreover, a direct current (DC) of about 40 A is applied to the wafer to form the polycrystal structure 320. The polycrystal structure 320 includes copper grains 324 with crystal structures having Miller indices of (100). The resultant polycrystal structure 320 would typically provide a relatively small bond area for a bond wire, such as 56% or less of an area of a bond pad to bond wire interface, and oxidation at this interface is also likely.

To increase the bond area, in FIG. 3, a second graph 340 depicts a pulsed plating operation for electroplating. The second graph 340 plots an applied current, in amperes (A) as a function of time in milliseconds (ms) employed to form a nanotwin copper (ntCu) structure 360. In the example illustrated, the current is pulsed at a frequency of about 5 to about 10 hertz (Hz) between current of about 40 A and a current less than 1 A. The pulsed current has a duty cycle of about 25% in some examples. In the example illustrated, it is presumed that a wafer 364 is immersed in a solution with a copper concentration of about 32 grams per liter (g/L) or about 55 g/L. It is understood that in other examples other concentrations are employable, such as copper concentrations between 30 g/L and 60 g/L. In examples where the 25% duty cycle is used, and the solution has a copper concentration of 32 g/L, the pulsed plating can be applied for about 22.22 minutes to form a plating that is about 10 μm thick. Thus, the pulsed plate rate in this situation is about 0.45 μm per minute (μm/min). In examples where the 25% duty cycle is used, and the solution has a copper concentration of 55 g/L, the pulsed plating can be applied for about 10.00 minutes to form a plating that is about 10 μm thick. Thus, the pulsed plate rate in this situation is about 1.0 μm/min. The nanotwin copper (ntCu) structure 360 formed with the pulsed plating operation characterized by the second graph 340 includes copper grains 368 that have crystal lattice structures with Miller indices of (111).

In contrast to the polycrystal structure 320, the nanotwin copper (ntCu) structure 360 is employable to implement the first copper bond pad 104 and/or the second copper bond pad 106 of FIG. 1. More particularly, the nanotwin copper (ntCu) structure 360 provides a high rate of atom diffusion, enabling the bond area (e.g., the bond 200 of FIG. 2) at the interface of the nanotwin copper (ntCu) structure 360 to be 70% to about 95%.

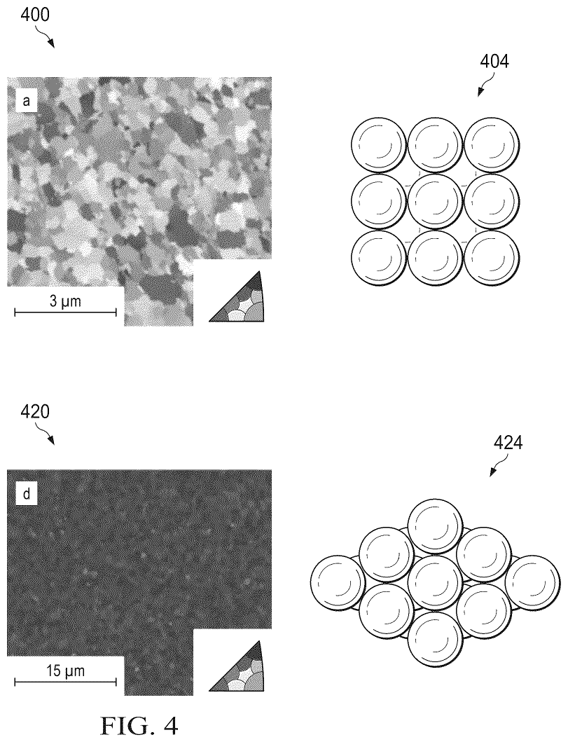

FIG. 4 illustrates a cross-section of a conventional polycrystal structure 400 that is formed with the direct plating operation characterized in the first graph 300 of FIG. 3. The conventional polycrystal structure 400 is formed with multiple instances of a crystal lattice structure 404. The crystal lattice structure 404 has a Miller index of (100). As noted, the conventional polycrystal structure 400 if used for a copper bond pad has limits on the bond area for a copper bond wire (e.g., 56% or less).

FIG. 4 also shows a cross-section of a nanotwin copper (ntCu) structure 420 that is formed with the pulsed plating operation characterized by the second graph 340 of FIG. 3. The nanotwin copper (ntCu) structure 420 is formed with multiple instances of a crystal structure 424 that has a Miller index of (111). In contrast to the random pattern formed by the conventional polycrystal structure 400, the nanotwin copper (ntCu) structure 420 has a continuous pattern to increase diffusivity of the nanotwin copper (ntCu) structure 420. Thus, as noted, the nanotwin copper (ntCu) structure 420 provides a high rate of atom diffusion, enabling the bond area (e.g., the bond 200 of FIG. 2) at the interface of the nanotwin copper (ntCu) structure 420 to be within a range of about 70% to about 95%.

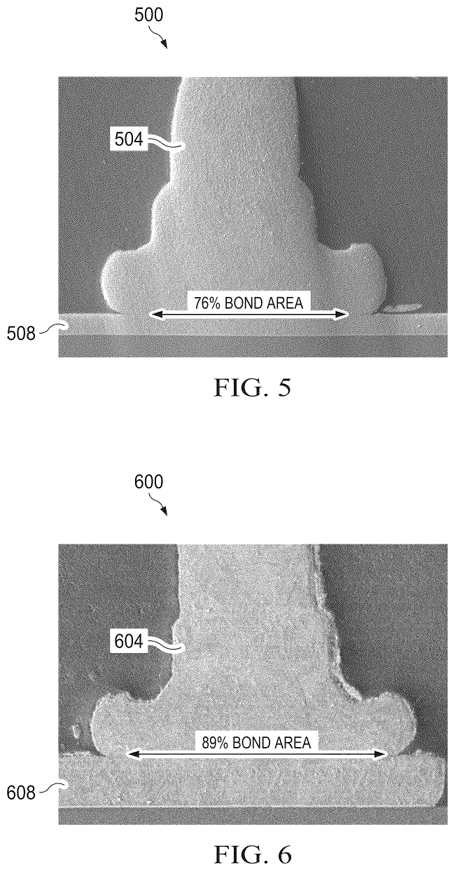

FIG. 5 illustrates an image 500 of a bond wire 504 attached to a nanotwin copper (ntCu) bond pad 508 having a copper grain with a crystal lattice structure having Miller indices of (111). The nanotwin copper (ntCu) bond pad 508 is employable to implement the first copper bond pad 104 and/or the second copper bond pad 106 of FIG. 1. The nanotwin copper (ntCu) bond pad 508 is formed with the pulsed plating operation for electroplating, as characterized by the second graph 340 of FIG. 3. More particularly, in the example illustrated, the nanotwin copper (ntCu) bond pad 508 is formed through electroplating with a solution having a copper concentration of 32 g/L. The nanotwin copper (ntCu) bond pad 508 has sufficient diffusion to enable a bond area at an interface of the bond wire 504 and the nanotwin copper (ntCu) bond pad 508 of about 76%. The bond area provides a conductive path between the bond wire 504 and the nanotwin copper (ntCu) bond pad 508.

FIG. 6 illustrates another image 600 of a bond wire 604 attached to a nanotwin copper (ntCu) bond pad 608 having a copper grain with a crystal lattice structure having Miller indices of (111). The nanotwin copper (ntCu) bond pad 508 is employable to implement the first copper bond pad 104 and/or the second copper bond pad 106 of FIG. 1. The nanotwin copper (ntCu) bond pad is formed with the pulsed plating operation for electroplating, as characterized by the second graph 340 of FIG. 3. More particularly, in the example illustrated, the nanotwin copper (ntCu) bond pad 608 is formed through electroplating with a solution having a copper concentration of 55 g/L. The nanotwin copper (ntCu) bond pad 608 has sufficient diffusion to enable a bond area at an interface of the bond wire 604 and the nanotwin copper (ntCu) bond pad 608 of about 89%. The bond area provides a conductive path between the bond wire 604 and the nanotwin copper (ntCu) bond pad 608.

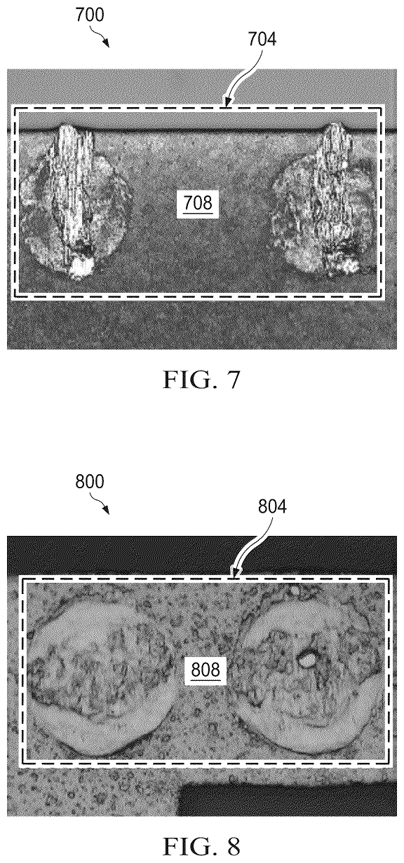

FIG. 7 illustrates an image 700 of a pair of bond wires 704 that have been sheared from a first nanotwin copper (ntCu) pad 708, such as the first copper bond pad 104 and/or the second copper bond pad 106 of FIG. 1. The nanotwin copper (ntCu) pad 708 is formed with the pulsed plating operation for electroplating characterized by the second graph 340 of FIG. 3. The nanotwin copper (ntCu) pad 708 is formed through electroplating with a solution that includes 32 g/L of copper.

FIG. 8 illustrates an image 800 of a pair of bond wires 804 that have been sheared from a second nanotwin copper (ntCu) pad 808, such as the first copper bond pad 104 and/or the second copper bond pad 106 of FIG. 1. The nanotwin copper (ntCu) pad 808 is formed with the pulsed plating operation for electroplating characterized by the second graph 340 of FIG. 3. The nanotwin copper (ntCu) pad 808 is formed through electroplating with a solution that includes 55 g/L of copper.

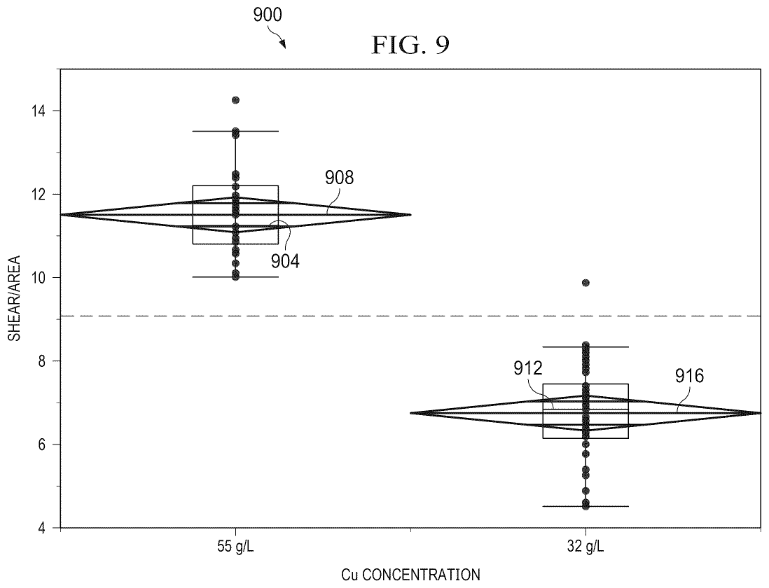

FIG. 9 illustrates a graph 900 that plots a shear area (labeled Shear/Area) of sample a nanotwin copper pad, measured in square micrometers (μm²) as a function of decreasing copper concentration in grams per liter (g/L) of a solution employed to form a corresponding nanotwin copper pad for a plurality of testes nanotwin copper (ntCu) pads. As illustrated, samples of nanotwin copper pads formed with a solution of 55 g/L have a shear area between about 9 μm² and about 15 μm². Moreover, these nanotwin copper pads have a median value of about 11 μm² as indicated by a line 904 and a mean value of about 11.4 μm² as indicated by a line 908. For the example provided, it is presumed that nanotwin copper pads formed through electroplating with a solution of 55 g/L, have a minimum shear area of about 9 μm². Thus, in the provided example the sample nanotwin copper pads have a shear area that is greater than the minimum shear area.

Further, as illustrated by the graph 900, samples of nanotwin copper pads formed with a solution of 32 g/L have a shear area between about 4.5 μm² and about 10 μm². Moreover, these nanotwin copper pads have a median value of about 11 μm² as indicated by a line 912 and a mean value of about 11.4 μm² as indicated by a line 916. For the example provided, it is presumed that nanotwin copper pads formed through electroplating with a solution of 32 g/L, have a minimum shear area of about 4 μm². Thus, in the provided example the sample nanotwin copper pads have a shear area that is greater than the minimum shear area.

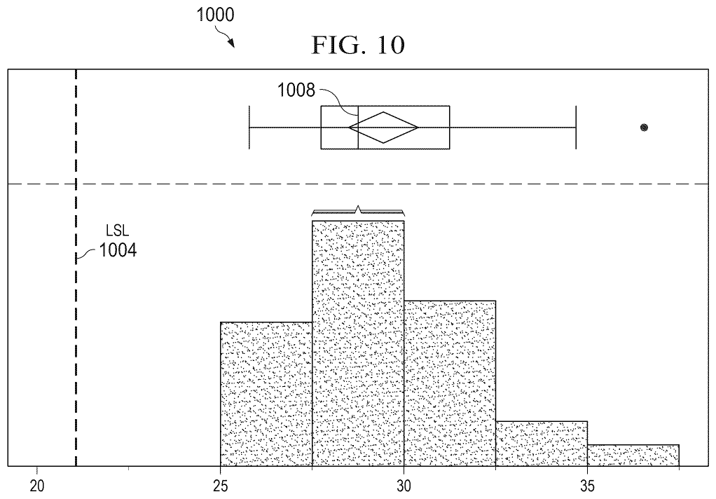

FIG. 10 illustrates a bar chart 1000 that plots a shear strength in grams-force per wire (gf/wire) for 30 samples of nanotwin copper pads formed through electroplating with a solution of 32 g/L or 55 g/L. One (1) gf/wire is equal to about 0.00980665 Newtons (N). In the example illustrated, the LSL (lower spec limit) 1004 represents a minimum allowable shear strength of about 23 gf/wire. The LSL 1004 is the same minimum shear strength for a pad that is formed with nickel (Ni) and palladium (Pd). As illustrated, the 30 samples of nanotwin copper pads have a shear strength of about 25 gf/wire to about 35 gf/wire, and a mean of about 29.505 gf/wire, as indicated by a line 1008. Thus, the sample nanotwin copper pads provide a shear strength that is above the LSL 1004 without the additional costs associated with nickel (Ni) and palladium (Pd).

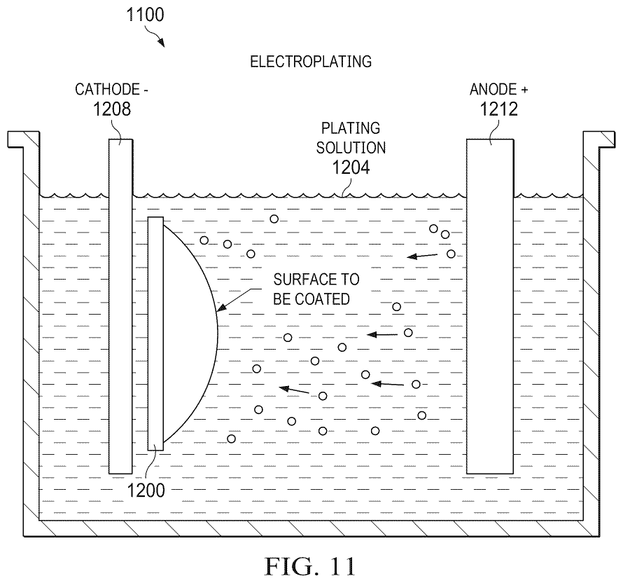

FIGS. 11-15 illustrate operations of a method for forming an IC package with a copper bond pad, such as the IC package 100 of FIG. 1. Thus, FIGS. 11-15 employ the same reference numbers to denote the same structures.

FIG. 11 illustrates a first stage 1100 of the method wherein a wafer 1200 is electroplated. The wafer 1200 includes multiple dies. The wafer 1200 is immersed (e.g., submerged) in a solution 1204 with a copper concentration of between 30 g/L and 60 g/L, such as a copper concentration of about 32 g/L or 55 g/L.

The wafer 1200 is coupled to a cathode 1208 and faces an anode 1212. A pulsed plating operation is executed for electroplating of copper pads onto the wafer 1200. The second graph 340 plots an applied current, in amperes (A) as a function of time in milliseconds employed to form a nanotwin copper (ntCu) structure 360. In the example illustrated, a current through the anode 1212 is pulsed at a frequency of about 5 to about 10 Hz between current of about 40 A and a current less than 1 A, forming a waveform similar to the waveform depicted in the second graph 340 of FIG. 3. The pulsed current has a duty cycle of about 25% in some examples. In examples where the solution 1204 has a copper concentration of about 32 g/L, the plating time (e.g., time for applying the pulsed current) is about 22.22 minutes to form a copper plate of about 10 μm thick. In examples where the solution 1204 has a concentration of about 32 g/L, the plating time is about 10.00 minutes to form a copper plate of about 10 μm thick. In some examples, the copper plate is a seed layer.

The wafer 1200 is removed from the solution 1204. Portions of the copper plate are removed by seed layer etching and/or photolithography techniques to form patterns for copper bond pads on dies of the wafer 1200. Additionally, in examples where photolithography techniques are used, a photoresist is applied on the wafer 1200 to form the patterns for the copper bond pads and exposed to light a specific frequency range. Subsequently, remaining photoresist is stripped. In some examples, a coating of anti-tarnish is applied to the wafer 1200 to impede corrosion of the copper pond pads formed on the wafer 1200. In such situations, the anti-tarnish coating is applied responsive to the electroplating operation.

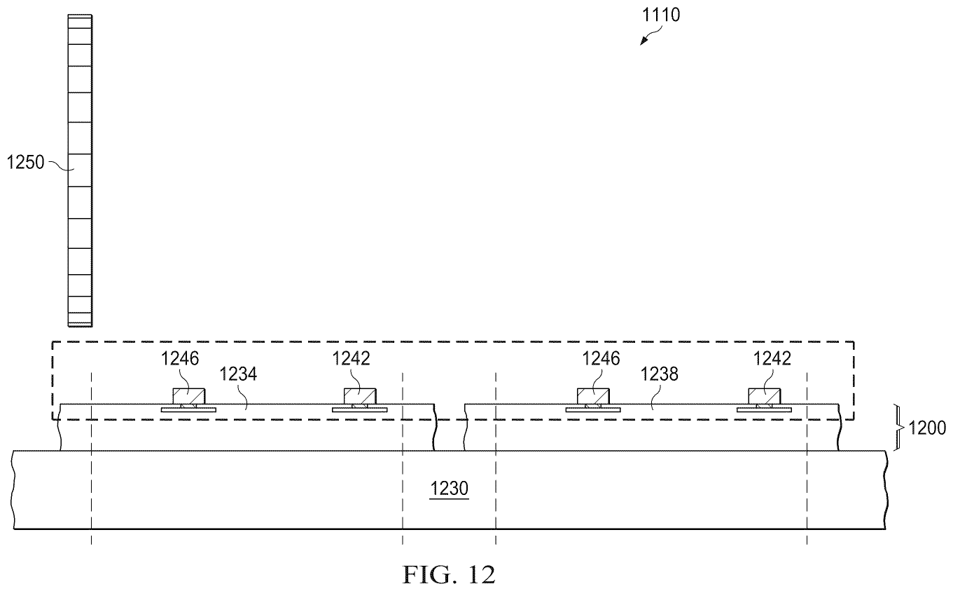

As illustrated in FIG. 12, in a second stage 1110, the wafer 1200 is placed on a dicing table 1230. In the example illustrated the wafer 1200 includes K number of dies, namely a first die 1234 and a Kth die 1238, where K is an integer greater than or equal to one (1). The first die 1234 and the Kth die 1238 have a first copper bond pad 1242 and a second copper bond pad 1246, such as the first copper bond pad 104 and the second copper bond pad 106 of FIG. 1. Thus, the first copper bond pad 1242 and the second copper bond pad 1246 are formed of nanotwin copper (ntCu). Also at 1110, a saw 1250, such as a laser saw, a diamond saw, a plasma saw, etc. is employed to dice the K number of dies from the wafer 1200 in a singulation operation. Stated differently, the K number of dies of the wafer 1200 are singulated using the saw 1250.

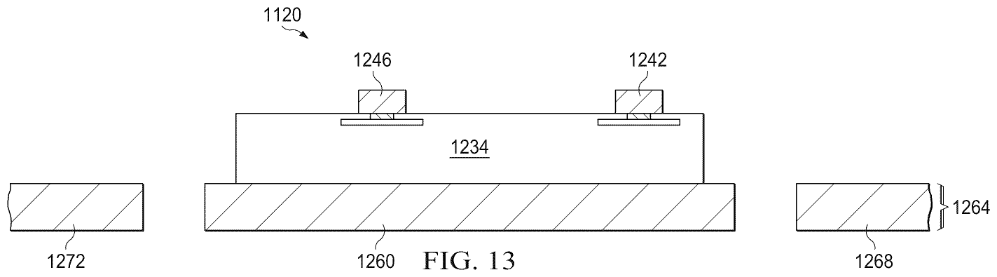

As illustrated in FIG. 13, in a third stage 1120, the first die 1234 is mounted on a die attach pad 1260 of an interconnect 1264 (e.g., a lead frame). The interconnect 1264 includes a first lead 1268 and a second lead 1272, but in other examples, the die attach pad 1260 includes more or less leads.

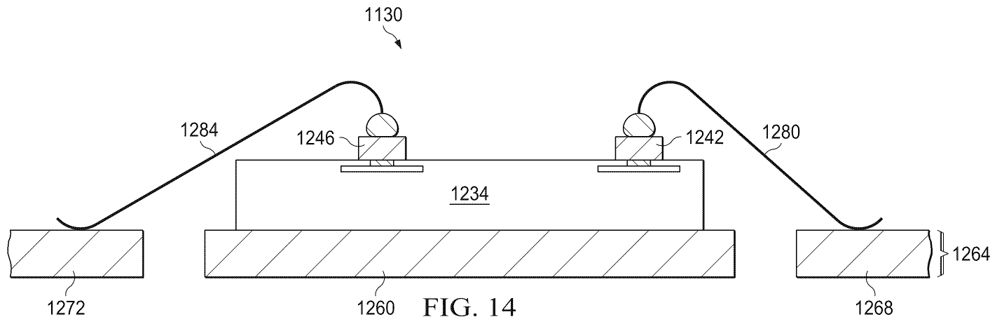

As illustrated in FIG. 14, in a fourth stage 1130, a first bond wire 1280 is attached to the first copper bond pad 1242 and a second bond wire 1284 is attached to the second copper bond pad 1246. Because the second copper bond pad 1246 and the first copper bond pad 1242 are formed with copper, the first bond wire 1280 forms a copper-to-copper (Cu—Cu) connection with the first copper bond pad 1242 and the second bond wire 1284 forms a copper-to-copper (Cu—Cu) connection with the second copper bond pad 1246.

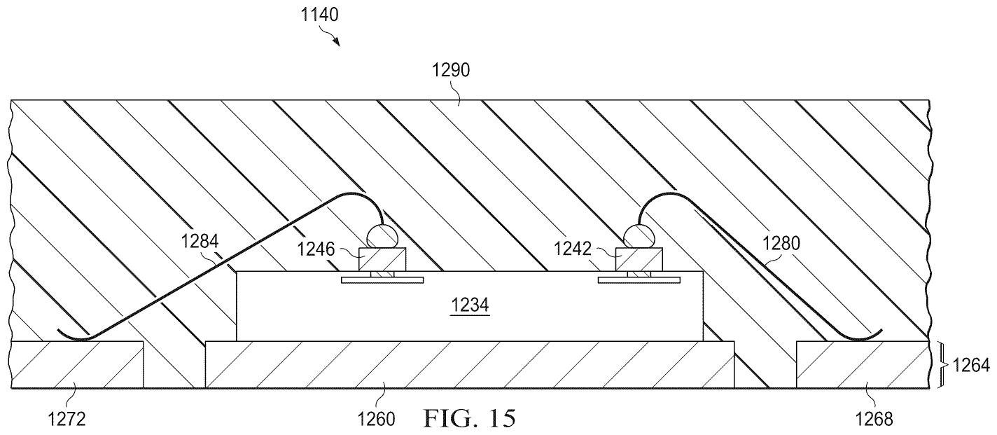

As illustrated in FIG. 15, in a fifth stage 1140, a mold compound 1290 is applied to the first die 1234 and the interconnect 1264 in a mold flow operation.

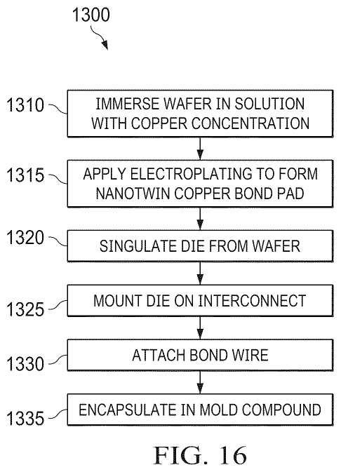

FIG. 16 illustrates a flowchart of an example method 1300 for fabricating an IC package with copper bond pads, such as the IC package 100 of FIG. 1. At block 1310, a wafer, such as the wafer 1200 of FIG. 11 is immersed (e.g., submerged) in a solution (e.g., the solution 1204 of FIG. 11) with a copper concentration of between 30 g/L and 60 g/L, such as a copper concentration of about 32 g/L or 55 g/L. In some examples, this solution is referred to as a plating solution.

At block 1315, electroplating is applied to the wafer. To apply the electroplating, a pulsed plating operation is executed to induce a current between an anode and a cathode immersed in the solution. The current is pulsed at a frequency of about 5 to about 10 Hz with a duty cycle of about 25% between current of about 40 A and a current less than 1 A, forming a waveform similar to the waveform depicted in the second graph 340 of FIG. 3. In examples where the solution has a copper concentration of about 32 g/L, the plating time (e.g., time for applying the pulsed current) is about 22.22 minutes to form a copper plate of about 10 μm thick. In examples where the solution has a concentration of about 32 g/L, the plating time is about 10.00 minutes to form a copper plate of about 10 μm thick. In some examples, the copper plate is a seed layer.

The wafer is removed from the solution. Portions of the copper are removed (e.g., using photolithography and/or seed layer etching techniques) in a die preparation operation to form forms nanotwin copper (ntCu) bond pads on the wafer Additionally, in examples where photolithography techniques are used, a photoresist is applied to the wafer form the patterns for the copper bond pads and exposed to light a specific frequency range. Subsequently, remaining photoresist is stripped. In some examples, a coating of anti-tarnish is applied to the wafer to impede corrosion of copper pads formed on the wafer.

At block 1320, a die (or multiple dies) is singulated from the wafer. The die includes nanotwin copper (ntCu) bond pads. In some examples, the singulation is executed with a saw, such as a laser saw, a plasma cutter or a diamond saw.

At block 1325, the die is mounted on a die attach pad (e.g., the die attach pad 116 of FIG. 1) of an interconnect (e.g., the interconnect 112 of FIG. 1). The interconnect includes a lead (or multiple leads). At block 1330, a bond wire (e.g., the first bond wire 140 of FIG. 1) is attached to the copper bond pad. Because the copper bond pad is formed with copper, the bond wire forms a copper-to-copper (Cu—Cu) connection with the copper bond pad. At block 1335 a mold compound (e.g., the mold compound 156 of FIG. 1) encapsulates the die and the interconnect in a mold flow operation.

In this description, unless otherwise stated, “about” preceding a parameter means being within +/−10 percent of that parameter. Modifications are possible in the described embodiments, and other embodiments are possible, within the scope of the claims.

What is claimed is:

1. A method for forming an IC (integrated circuit) package comprising:
electroplating a wafer to form a nanotwin copper bond pad on the wafer, wherein the electroplating comprises applying a pulsed current to the wafer immersed in a plating solution, and the nanotwin copper bond pad is formed with a copper grain that includes a crystal lattice structure that has Miller indices of 111;
singulating a die from the wafer, wherein the die comprises the nanotwin copper bond pad;
mounting the die on an interconnect; and
attaching a bond wire to the nanotwin copper bond pad to form a copper-to-copper bond between the bond wire and the nanotwin copper bond pad.

2. The method of claim 1, further comprising encapsulating the die, the interconnect and the bond wire in a mold compound.

3. The method of claim 1, wherein the plating solution has a copper concentration of about 32 grams per liter to about 60 grams per liter.

4. The method of claim 1, wherein the plating solution has a copper concentration of about 55 grams per liter to about 60 grams per liter.

5. The method of claim 1, wherein the pulsed current has a duty cycle of about 25%.

6. The method of claim 5, wherein the pulsed current has a frequency of about 5 hertz.

7. The method of claim 1, wherein the nanotwin copper bond pad of the wafer has a thickness of about 6 micrometers to about 15 micrometers and a width of about 15 micrometers to about 55 micrometers.

8. The method of claim 1, further comprising applying an anti-tarnish coating on the wafer responsive to the electroplating.

9. The method of claim 1, wherein the copper-to-copper bond has a bond area of about 70% to about 95% of an interface between the bond wire and the nanotwin copper bond pad.

10. A method for forming an IC (integrated circuit) package comprising:
singulating a die from a wafer, the die comprising a nanotwin copper bond pad coupled to a circuit embedded in the die, wherein the nanotwin copper bond pad is formed with a copper grain that includes a crystal lattice structure that has Miller indices of 111;
mounting the die on an interconnect; and
attaching a bond wire to the nanotwin copper bond pad to form a copper-to-copper bond between the bond wire and the nanotwin copper bond pad and to couple the circuit embedded in the die to a lead of the interconnect.

11. The method of claim 10, wherein the nanotwin copper bond pad has a thickness of about 6 micrometers to about 15 micrometers.

12. The method of claim 11, wherein the nanotwin copper bond pad has a width of about 15 micrometers to about 55 micrometers.

13. The method of claim 10, wherein the copper-to-copper bond has a bond area of about 70% to about 95% of an interface between the bond wire and the nanotwin copper bond pad.

14. An IC (integrated circuit) package comprising:
a die having a nanotwin copper bond pad coupled to a circuit embedded in the die, wherein the nanotwin copper bond pad is formed with a copper grain that includes a crystal lattice structure that has Miller indices of 111; and
a bond wire coupled to the nanotwin copper bond pad and to a lead of an interconnect, wherein the bond wire and the nanotwin copper bond pad form a copper-to-copper bond.

15. The IC package of claim 14, wherein the nanotwin copper bond pad is a BOAC (bond over active circuit) connection.

16. The IC package of claim 14, wherein the nanotwin copper bond pad has a thickness of about 6 micrometers to about 15 micrometers.

17. The IC package of claim 16, wherein the nanotwin copper bond pad has a width of about 15 micrometers to about 55 micrometers.

18. The IC package of claim 14, wherein the copper-to-copper bond has a bond area of about 70% to about 95% of an interface between the bond wire and the nanotwin copper bond pad.

19. The IC package of claim 14, wherein the nanotwin copper bond pad is distal to an edge of the die.

20. The IC package of claim 14, further comprising a mold compound encapsulating the die, the interconnect and the bond wire.
